(19) United States
(12) Patent Application Publication
(10) Pub. No.: US 2026/0324079 A1
(43) Pub. Date: Oct. 15, 2026

(54) ELECTRONIC DEVICE WITH INSPECTION CIRCUIT

(71) Applicant: Innolux Corporation, Miaoli County (TW)

(72) Inventor: Shuhei Hosaka, Miaoli County (TW)

(73) Assignee: Innolux Corporation, Miaoli County (TW)

(21) Appl. No.: 19/533,271

(22) Filed: Feb. 8, 2026

Related U.S. Application Data
(60) Provisional application No. 63/785,641, filed on Apr. 9, 2025.

(51) Int. Cl. H10D 86/40

(52) U.S. Cl. CPC H10D 86/441

(57) ABSTRACT

The present disclosure provides an electronic device including a substrate including an active region, a first data line disposed on the substrate and extending along a first direction, a first pixel unit disposed on the substrate within the active region and electrically connected to the first data line, a second pixel unit disposed on the substrate within the active region and electrically connected to the first data line, and an inspection circuit disposed on the substrate within the active region and including a signal line, a first switching component electrically connected to the first signal line and the first data line and disposed between the first and second pixel units, and a first control line extending electrically connected to a control terminal of the first switching component.

### CROSS-REFERENCE TO RELATED APPLICATION

This application claims the priority benefit of U.S. provisional application serial no. 63/785,641, filed on Apr. 9, 2025. The entirety of the above-mentioned patent application is hereby incorporated by reference herein and made a part of this specification.

### BACKGROUND

### Technical Field

The present disclosure relates to an electronic device, and particularly relates to the electronic device with an inspection circuit.

### Description of Related Art

With the continuous progress of the technology industry, display devices have been extensively adopted in various products such as televisions, computers, and mobile phones. Recently, narrow-bezel displays have become a prevailing trend in the development of high-quality display devices due to their advantages of simplified appearance, enhanced aesthetics, and an increased display area in a given panel size. However, the arrangement of various components disposed in the display region is constrained by the limited space. Accordingly, there is a continuous need for further improvements in integrating certain components, which were originally arranged in the peripheral region, into the display region so as to satisfy current or future needs.

### SUMMARY

According to an embodiment of the present disclosure, the electronic device includes a substrate comprising an active region, a first data line disposed on the substrate and extending along a first direction, a first pixel unit disposed on the substrate within the active region and electrically connected to the first data line, a second pixel unit disposed on the substrate within the active region and electrically connected to the first data line, and an inspection circuit disposed on the substrate within the active region. The inspection circuit includes a first signal line, a first switching component electrically connected to the first signal line and the first data line and disposed between the first pixel unit and the second pixel unit, and a first control line electrically connected to a control terminal of the first switching component.

To make the features and advantages of the disclosure more comprehensible, several embodiments accompanied with drawings are described in detail as follows.

### BRIEF DESCRIPTION OF THE DRAWINGS

FIG. 1 is a schematic view illustrating an electronic device according to a first embodiment of the present disclosure.

FIG. 2 is a schematic circuit diagram showing an inspection circuit according to an embodiment of the present disclosure.

FIG. 3 is a schematic top view illustrating an inspection circuit according to an embodiment of the present disclosure.

FIG. 4 is a cross-sectional view taken along line A-A’ in FIG. 3 according to an embodiment of the present disclosure.

FIG. 5 is a cross-sectional view taken along line B-B’ in FIG. 3 according to an embodiment of the present disclosure.

FIG. 6 is a schematic view illustrating an electronic device according to a second embodiment of the present disclosure.

FIG. 7 is a schematic view illustrating an electronic device according to a third embodiment of the present disclosure.

FIG. 8 is a schematic enlarged view showing a first region of the electronic device according to the third embodiment of the present disclosure.

FIG. 9 is a schematic enlarged view showing a second region of the electronic device according to the third embodiment of the present disclosure.

FIG. 10 is a schematic enlarged view showing a third region of the electronic device according to the third embodiment of the present disclosure.

FIG. 11 is a schematic view showing an electronic device according to a fourth embodiment of the present disclosure.

FIG. 12 is a schematic view illustrating an electronic device according to a fifth embodiment of the present disclosure.

FIG. 13 is a schematic view illustrating an electronic device according to a sixth embodiment of the present disclosure.

FIG. 14 is a schematic view showing an additional inspection circuit according to an embodiment of the present disclosure.

FIG. 15 is a schematic view illustrating an electronic device according to a seventh embodiment of the present disclosure.

### DESCRIPTION OF THE EMBODIMENTS

The electronic device may be or include a rollable display device, a flexible display device, a free-form display device, or a tiled display device, but the present disclosure is not limited thereto. The electronic device may include a non-self-luminous panel such as a liquid crystal panel or other self-luminous panels, but the present disclosure is not limited thereto.

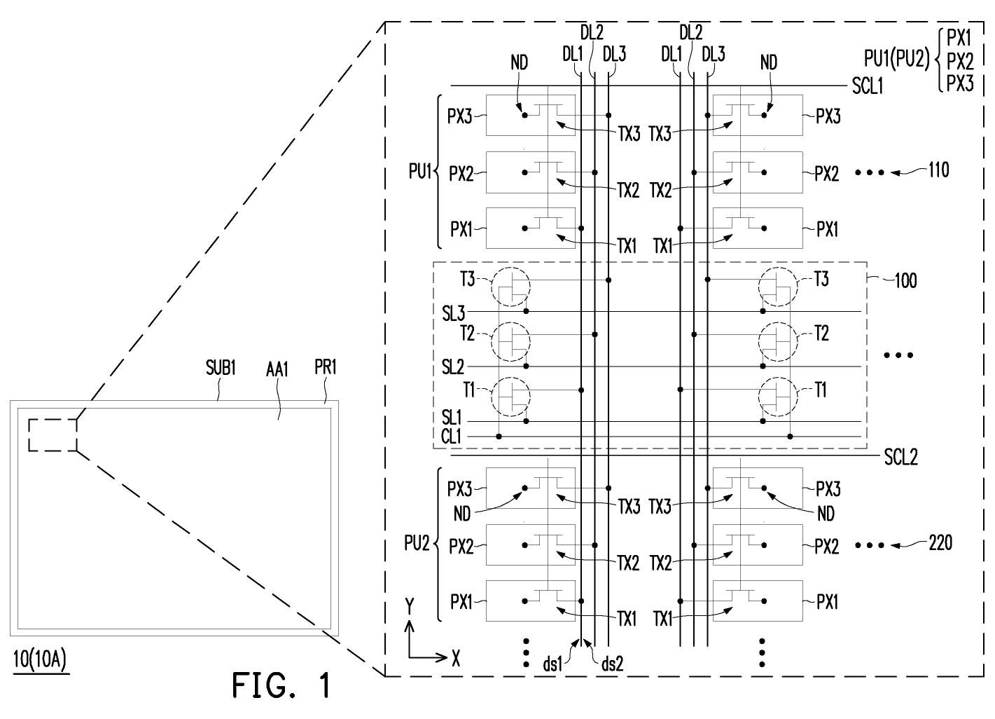

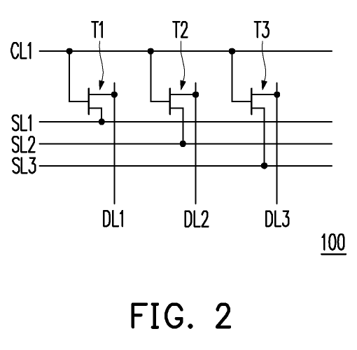

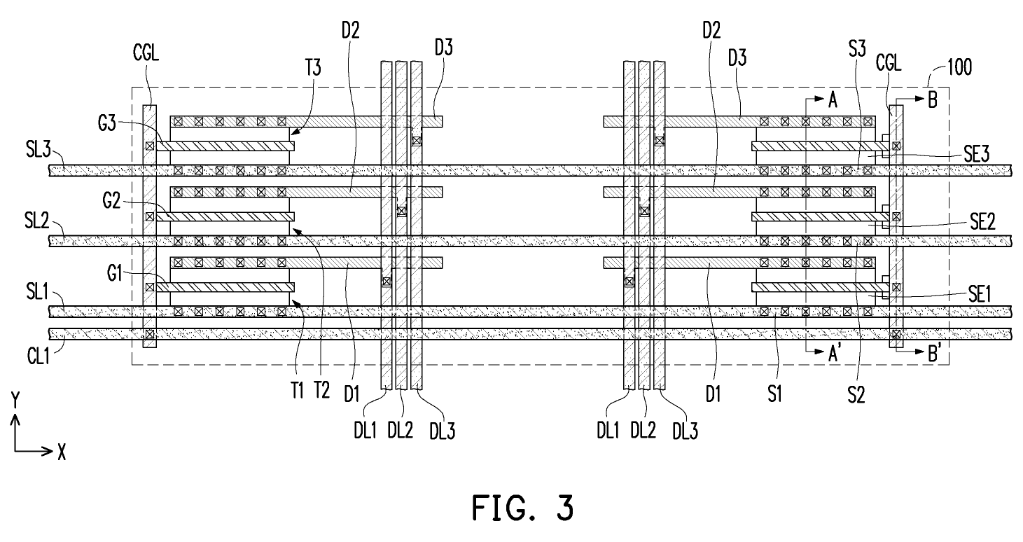

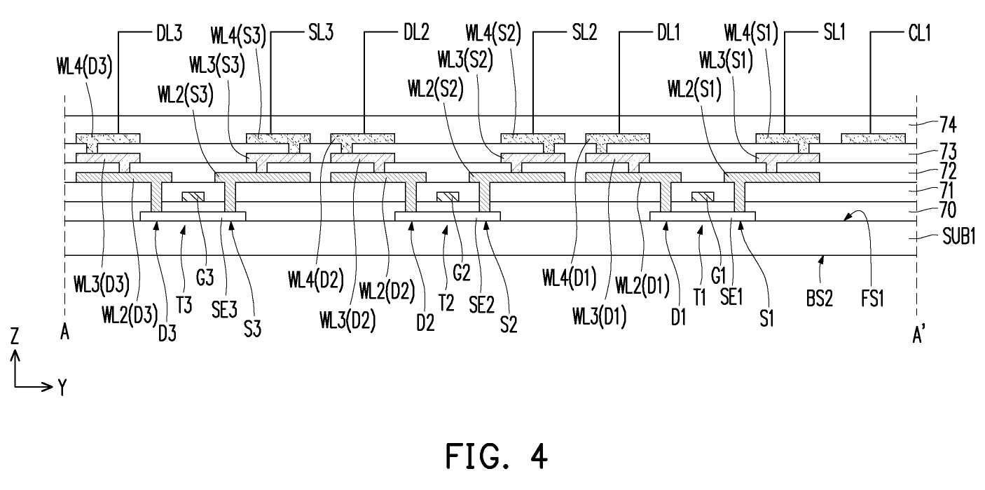

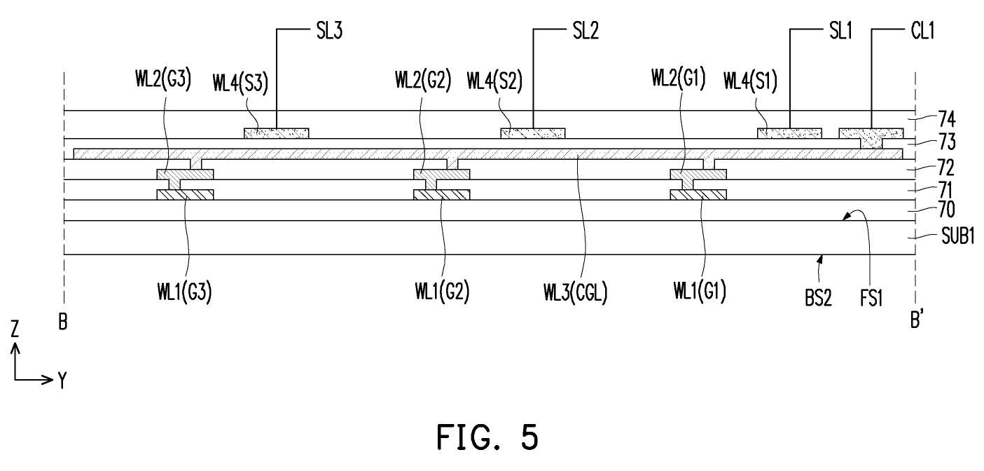

FIG. 1 is a schematic view illustrating an electronic device according to a first embodiment of the present disclosure. FIG. 2 is a schematic circuit diagram showing an inspection circuit according to an embodiment of the present disclosure. FIG. 3 is a schematic top view illustrating an inspection circuit according to an embodiment of the present disclosure. FIG. 4 is a cross-sectional view taken along line A-A’ in FIG. 3 according to an embodiment of the present disclosure. FIG. 5 is a cross-sectional view taken along line B-B’ in FIG. 3 according to an embodiment of the present disclosure.

Referring to FIG. 1, an electronic device (e.g., an electronic device 10) of the present disclosure includes a substrate SUB1 having an active region AA1 and a peripheral region PR1. The peripheral region PR1 is adjacent to the active region AA1. In some embodiments, the peripheral region PR1 can surround the active region AA1. In some embodiments, the electronic device can be a display device, for example, a light emitting diode display device.

In the illustrated embodiment shown in FIG. 1, the electronic device 10 includes a plurality of data lines DL, a plurality of scan line SCL, a plurality of pixel units PU, and an inspection circuit 100, disposed on the substrate SUB1. The plurality of data lines DL can extend along a first direction Y, and the plurality of scan line SCL can extend along a second direction X different from the first direction Y. For easy explanation, only two scan lines SCL1 and SCL2 are shown in FIG. 1, but not limiting the scope of this application. The plurality of data lines DL can cross the plurality of scan line SCL. The plurality of data lines can include a first data line DL1, a second data line DL2, and a third data line DL3 adjacent to each other along the second direction X. The plurality of pixel units PU are disposed on the substrate SUB1 in the active region AA, and there is no pixel unit in the peripheral region PR. The plurality of pixel units PU can include a first pixel unit PU1 and a second pixel unit PU2. Each pixel unit, for example, the first pixel unit PU1 can include a first pixel (or sub-pixel) PX1 electrically connected to the first data line DL1, a second pixel (or sub-pixel) PX2 electrically connected to the second data line DL2, and a third pixel (or sub-pixel) PX3 electrically connected to the third data line DL3. The first pixel PX1, the second pixel PX2, and the third pixel PX3 may be arranged adjacent to each other along the first direction Y. In some embodiments, the first direction may cross the second direction. In some alternative embodiments, the first direction may be perpendicular to the second direction.

Referring to FIG. 1, the inspection circuit 100 can be disposed on the substrate SUB1 within the active region AA1. The inspection circuit 100 can include a first signal line SCL1, a first switching component T1, and a first control line CL1. The plurality of pixel units PU can be divided into a first row 110 of pixel units electrically connected to the first scan line SCL1, and a second row 220 of pixel units electrically connected to the second scan line SCL2. Specifically, the inspection circuit 100 can be disposed between the first row 110 of pixel units and the second row 220 of pixel units.

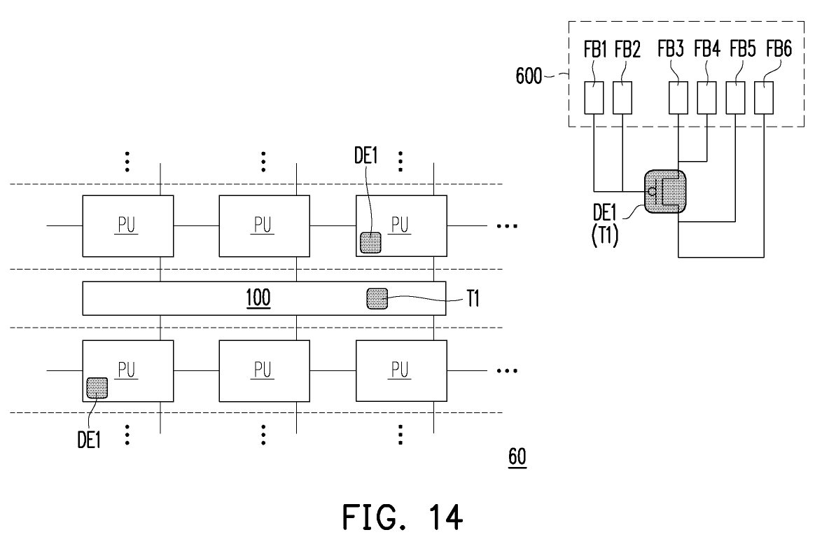

Referring to FIG. 1, in some embodiments, the pixel unit PU can include an electronic component DE1, as simply shown in FIG. 14. Specifically, each of the first pixel PX1, the second pixel PX2, and the third pixel PX3 may include an electronic component. For example, the first pixel PX1 can include an electronic component DE1. The electronic component can include active components, passive components, electrodes, conductive wirings, or combinations thereof. The active components may include switching components such as transistors TX (e.g., thin film transistors (TFTs)) and light-emitting components, a quantum dot (QD), a fluorescence, a phosphor, other suitable materials, or combinations thereof. The active components can include driving transistors. The passive devices may include capacitors, resistors, inductors, or combinations thereof. The light-emitting component can be a light emitting diode. The light emitting diode may include, for example, an organic light emitting diode (OLED), an inorganic light emitting diode, a mini-LED, a micro-LED, or a quantum dot light emitting diode (QLED, QDLED), but is not limited thereto. The conductive wirings may include signal lines such as data lines, scan lines, or combinations thereof.

Referring to FIG. 1, in one pixel unit PU, the first pixel PX1, the second pixel PX2, and the third pixel PX3 can display different colors. For example, the first pixel PX1 displays a first color, the second pixel PX2 displays a second color, and the third pixel PX3 displays a third color. The first color, the second color and the third color are different. For example, the first color is red, the second color is green, and the third color is blue, but the scope of this invention is not limited. In some embodiment, the first pixel PX1 can include the light emitting diode of the first color, the second pixel PX2 can include the light emitting diode of the second color, and the third pixel PX3 can include the light emitting diode of the third color.

In the illustrated embodiment shown in FIG. 1, for ease of understanding, only one transistor TX in one pixel PX is shown in FIG. 1, but not limiting the scope of this application. For example, only one transistor TX1 in the first pixel PX1 is shown in FIG. 1. Each pixel PX may include one or more transistors. The transistor TX1 is disposed in the first pixel PX1 and electrically connected to the first data line DL1, a transistor TX2 is disposed in the second pixel PX2 and electrically connected to the second data line DL2, and a transistor TX3 is disposed in the third pixel PX3 and electrically connected to the third data line DL3. The first row 110 of the pixel units is electrically connected to the first scan line SCL1. For example, in the first row 110, the transistors TX1, TX2, and TX3 are electrically connected to the first scan line SCL1. In some embodiments, the transistor TX include a node ND electrically connected to the electrode or light emitting component in the corresponding pixel PX. For clarity, FIG. 1 only shows the node ND of the transistor TX3 in the pixel PX3.

Referring to FIG. 1, the inspection circuit 100 includes a signal line (e.g., a first signal line SL1), a switching component (e.g., a first switching component T1) electrically connected to the signal line and the data line (e.g., DL1) and disposed between the first pixel unit PU1 and the second pixel unit PU2, and a control line (e.g., a first control line CL1) electrically connected to a control terminal of the switching component T1. In some embodiments, at least portion of the signal line and at least a portion of the control line extend along the second direction.

In the illustrated embodiment shown in FIGS. 1 and 2, the inspection circuit 100 includes a plurality of signal lines including a first signal line SL1, a second signal line SL2, and a third signal line SL3 that are adjacent to each other and extend along the second direction X, and a plurality of switching components including a first switching component T1 electrically connected to the first data line DL1 and the first signal line SL1, a second switching component T2 electrically connected to the second data line DL2 and the second signal line SL2, and a third switching component T3 electrically connected to the third data line DL3 and the third signal line SL3. In some embodiments, the first switching component T1, the second switching component T2, and the third switching component T3 may be transistors such as TFTs, but the present disclosure is not limited thereto. In the illustrated embodiment shown in FIG. 1, the first switching component T1, the second switching component T2, and the third switching component T3 are adjacent to each other in the first direction Y and are positioned at the same side of the first data line DL1, the second data line DL2, and the third data line DL3. For example, the first data line DL1 has a first side ds1 and a second side ds2 oppositely disposed, the second side ds2 is closer to the second data line DL2 than the first side ds1, and the first and second switching components T1 and T2 are at the first side ds1 of the first data line DL1. The second switching component T2 is disposed between the first pixel unit PU1and the second pixel unit PU2.

Referring to FIG. 1, in an inspection mode, a control signal is provided to the first control line CL1 to turn on the first switching component T1, and a test signal is provided to the first signal line. Thus, the first data line DL1 electrically connected to the first switching component T1 receives the test signal and controls the corresponding pixel PX1 to be enabled, thereby achieving electrical test. That is, at least one switching component is electrically connected to each data line, at least one signal line is electrically connected to a terminal of the switching component, and at least one control line is electrically connected to the control terminal of the switching component, thus achieving electrical test. Similarly, the second and third data lines DL2 and DL3 can receive the corresponding test signals respectively, and repeated descriptions are omitted. In the inspection mode, the plurality of scan lines SCL can be scanned sequentially from the first scan line to the last scan line, thus achieving electrical test for the entire pixel units (entire rows of the pixel units) on the substrate SUB1. In some embodiments, for pixels including emitting elements, such electrical test can be lighting test. Since the inspection circuit is disposed in the active region AA1, rather than in the peripheral region, the area of the peripheral region can be minimized, thus achieving a narrow border or borderless design. In addition, for a given size of a substrate, the pixel units can occupy a greater area of the substrate, thus achieving a greater utilization for the substrate.

Referring to FIG. 1, the electronic device 100 includes an array substrate 10A. The array substrate 10A includes the substrate SUB1, the plurality of data lines, the plurality of scan lines, the plurality of pixel units, and the inspection circuit 100. After the electrical test by means of the inspection circuit 100 is done for the array substrate 10A, other components, for example, a circuit board (not shown) can be combined to the array substrate 10A. The circuit board can be a printed circuit board and/or a flexible circuit board. For example, the circuit board can include a data driver (not shown) electrically connected to the plurality of data lines and providing data signals to the data lines in a driving mode.

In the illustrated embodiments shown in FIGS. 1 and 2, when the driving mode for the first to third pixels PX1 to PX3 is activated, the first to third switching components T1 to T3 in the inspection circuit 100 are in an off state to isolate the inspection circuit 100 from the first to third data lines DL1 to DL3. In some embodiments, when the driving mode is activated, the first to third signal lines SL1 to SL3 of the inspection circuit 100 are in a floating state, and a turn-off voltage is provided to the first control line CL1 of the inspection circuit 100 depending on the transistor type of the first to third switching components T1 to T3 to control the first to third switching components T1 to T3 in the off state. In some embodiments, the first to third switching components T1 to T3 may be or include n-type transistors, so that the reliability of the inspection circuit 100 may be improved. For example, the n-type transistors having a normally-off characteristic are beneficial for maintaining the off state of the first to third switching components T1 to T3 during the driving mode. In the illustrated embodiments shown in FIGS. 1 and 2, when the inspection mode for the first to third pixels PX1 to PX3 is activated, the first to third switching components T1 to T3 are in an on state, so that the inspection circuit 100 is electrically connected to the first to third data lines DL1 to DL3. In some embodiments, when the inspection mode is activated, respective test voltages are applied to the first to third signal lines SL1 to SL3 depending on various inspection purposes, and a turn-on voltage is provided to the first control line CL1 depending on the transistor type of the first to third switching components T1 to T3 to control the first to third switching components T1 to T3 in the on state. For ease of explanation, the figures only show that the switching components T1 to T3 in the inspection circuit and the transistors TX1 to TX3 in the pixel unit PU1 are n-type transistors. In some embodiments, the switching components and the transistors TX1 to TX3 can be p-type transistors.

Referring to FIGS. 1 and 3, the inspection circuit 100 includes a common gate line CGL electrically connected the control line CL1 to the first switching component T1, the second switching component T2, and the third switching component T3. That is, the first control line CL1 is electrically connected to control terminals of the first to third switching components T1 to T3. In this embodiment, the common gate line CGL extends along the first direction Y.

In the illustrated embodiment shown in FIGS. 3 and 4, the substrate SUB1 includes a first surface (e.g., a front surface) FS1 and a second surface (e.g., a back surface) BS2 oppositely disposed. The inspection circuit 100 is disposed on the first surface FS1 of the substrate SUB1. On the first surface FS1 of the substrate SUB1, a wiring layer WL1, a wiring layer WL2, a wiring layer WL3, and a wiring layer WL4 are sequentially disposed. A semiconductor layer SE is disposed on or below the wiring layer WL1. An insulating layer 71 is disposed between the wiring layers WL1 and WL2, an insulating layer 72 is disposed between the wiring layers WL2 and WL3, an insulating layer 73 is disposed between the wiring layers WL3 and WL4, an insulating layer 74 is disposed on the wiring layer WL4. The wiring layers WL1 to WL4, and the semiconductor layer SE are patterned according to needs to obtain the inspection circuit 100. FIG. 4 shows that the first switching component T1 may be a top-gate type thin film transistor. In the first switching component T1, a first gate G1 of the wiring layer WL1 is disposed on a first semiconductor layer SE1. An insulating layer 70 is disposed between the first gate G1 and the first semiconductor layer SE1. However, a bottom-gate type thin film transistor or other forms of transistor can be used and are within the scope of this application. The above-mentioned insulating layer can be a single layer, or a multiple layers. The insulating layer can include an organic layer, inorganic layer, or combinations thereof. For example, the insulating layer can be silicon oxide, silicon nitride, or combinations thereof, but the disclosure is not limited.

Referring to FIGS. 3 and 4, the first semiconductor layer SE1 includes a source end S1 and a drain end D1 positioned at opposite sides of the first gate G1. The first semiconductor layer SE1 may include suitable semiconductor materials such as single crystal silicon, amorphous silicon, polysilicon, metal oxide, or mixtures thereof. The metal oxide suitable can be IGZO (indium gallium zinc oxide). The wiring layers WL1, WL2, WL3 and WL4 can include any suitable conductive material. For example, the conductive material can be metal, for example, copper (Cu), aluminum (Al), molybdenum (Mo), tungsten (W), gold (Au), chromium (Cr), nickel (Ni), platinum (Pt), titanium (Ti), iridium (Ir), rhodium (Rh), alloys thereof, combinations thereof, or other metal materials with good conductivity, but are not limited thereto. The wiring layers WL1, WL2, WL3 and WL4 can include the same material or different materials. Each of the wiring layers WL1, WL2, WL3 and WL4 can include a single layer or multiple layers.

Referring to FIGS. 3-5, in some embodiments, the wiring layer WL1 can include the gates G1, G2, and G3. The wiring layer WL3 can include the common gate line CGL, and the data lines DL1, DL2, and DL3. The wiring layer WL4 can include the control line CL. The signal lines SL1, SL2, SL3 can be of the same layer as the control line CL, or of different layers from the control line CL. For example, the wiring layer WL4 can include the control line CL, and the signal lines SL1, SL2, and SL3. In some embodiments, the data lines, the signal lines, the control line, the common gate line, and the gates can be of wiring layers different from the wiring layers as mentioned above, for example, the control line CL can be of the wiring layer WL3, rather than the wiring layer WL4. Other variations for the wiring layers can be made, and detailed descriptions are omitted for clarity.

Referring to FIGS. 3-5, in the first switching component T1, the first gate G1 may be electrically connected to the control line CL1 through the common gate line CGL. Specifically, the first gate G1 of the wiring layer WL1 is electrically connected to a portion of the wiring WL2 via the via hole in the insulating layer 71, electrically connected to the common gate line CGL of the wiring layer WL3 via the via hole in the insulating layer 72, and electrically connected to the control line CL1 of the wiring layer WL4 via the via hole in the insulating layer 73. In FIG. 3, a plurality of cross symbols are shown, and the cross symbol can refer to the via hole in the insulating layer.

Referring to FIGS. 3-5, in the first switching component T1, the source end S1 of the first semiconductor layer SE1 is electrically connected to the first signal line SL1 through the wiring layer WL2 and the wiring layer WL3. Specifically, the source end S1 is electrically connected to a portion of the wiring WL2 via the via hole in the insulating layer 71, electrically connected to a portion of the wiring WL3 via the via hole in the insulating layer 72, and electrically connected to first signal line SL1 of the wiring layer WL4 via the via hole in the insulating layer 73. The drain end D1 of the first semiconductor layer SE1 is electrically connected to the first data line DL1 through the wiring layer WL2, the wiring layer WL3, and the wiring layer WL4 (referring to WL2(D1), WL3(D1) and WL4(D1) shown in FIG. 4). The drain end D1 can be electrically connected to the first data line DL1 of the wiring layer WL3. The drain end D1 can extend along the second direction X, and the data line DL1 can extend along the first direction Y. The design of the switching components T2 and T3 shown in FIGS. 3 to 5 can refer to the above descriptions for the switching components T1, and redundant detailed descriptions are omitted for clarity.

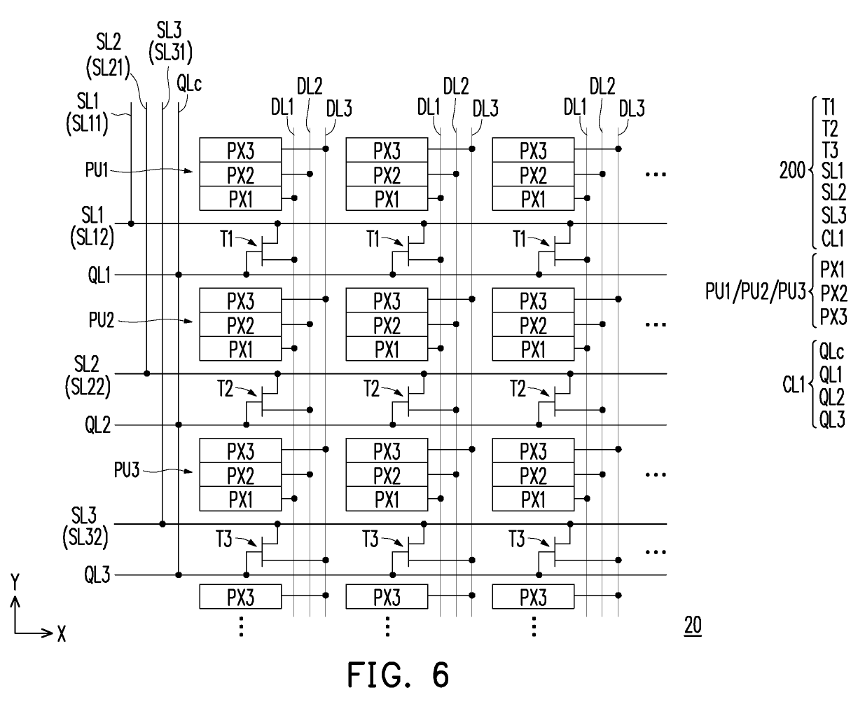

FIG. 6 is a schematic view illustrating an electronic device according to a second embodiment of the present disclosure. The main difference between an electronic device 20 shown in FIG. 6 and the electronic device 10 shown in FIG. 1 is the configuration of an inspection circuit 200 included in the electronic device 20. The electronic device 20 further includes a third pixel unit PU3 disposed on the substrate SUB1 within the active region AA1 and electrically connected to the first data line DL1. In the inspection circuit 200 shown in FIG. 6, the second switching component T2 is disposed between the second and third pixel units PU2 and PU3, the first switching component T1 is disposed between the first and second pixel units PU1 and PU2, and the third pixel unit PU3 is disposed between the second and third switching components T2 and T3. In the first direction Y, the first switching components T1 may be arranged between the first and second signal lines SL1 and SL2, the second switching components T2 may be arranged between the second and third signal lines SL2 and SL3, and the third signal line SL3 may be arranged between the second and third switching components T2 and the T3.

Referring to FIG. 6, the control line CL1 may include a first segment (connection portion) extending along the first direction Y and a second segment (main portion) extending along the second direction X. Each switching component can have its own control line. For example, the control terminals of the switching components T1, T2, T3 are electrically connected to the control lines QL1, QL2, QL3 respectively. Specifically, the control line CL1 can include the control line QLc (first segment) extending along the first direction Y, and control lines QL1, QL2, and QL3 (second segments) extending along the second direction X. The control lines QL1, QL2, and QL3 are electrically connected to the control line QLc, and the control signal can be provided from the control line QLc. Similarly, the signal line SL1 may include a first segment (connection portion) SL11 extending along the first direction Y and a second segment (main portion) SL12 extending along the second direction X. Similarly, the signal line SL2 may include the segment SL21 extending along the direction Y and SL22 extending along the direction X, and the signal line SL3 may include the segment SL31 extending along the direction Y and the segment SL32 extending along the direction X. The connections for signal lines SL1, SL2, and SL3 can refer to the above descriptions, and detailed descriptions are omitted for clarity. The first switching component T1 is arranged between the signal line SL1 and the control line QL1, the second switching component T2 is arranged between the signal line SL2 and the control line QL2, and the third switching component T3 is arranged between the signal line SL3 and the control line QL3.

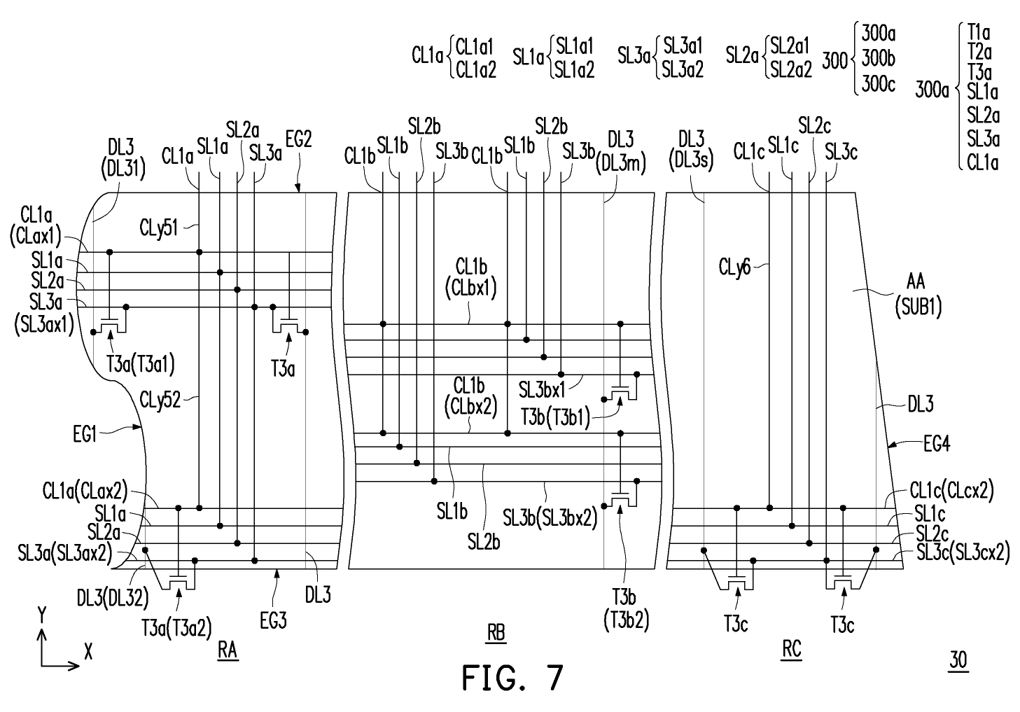

FIG. 7 is a schematic view illustrating an electronic device according to a third embodiment of the present disclosure. In FIG. 7, the electronic device 30 includes the substrate SUB1 having a free shape (e.g., a non-rectangular shape). For example, the substrate SUB1 includes a first edge EG1, a second edge EG2, a third edge EG3, and a fourth edge EG4, which are connected to each other. In some embodiments, the second edge EG2 and the third edge EG3 may be parallel and extend along the second direction X. The first edge EG1 and the fourth edge EG4 may have an irregular contour, for example, neither parallel to the first direction Y nor the second direction X. The substrate SUB1 includes a first region RA, and a second region RB, and a third region RC, and the second region RB is disposed between the first and third regions RA and RC. In this embodiment, the first region RA may be an irregular region such as a non-rectangular region having the edge EG1 with an irregular contour (e.g., a curved contour). The third region RC may be an irregular region such as a non-rectangular region having the edge EG4 with an irregular contour (e.g., an inclined line contour). The second region RB may be a rectangular region.

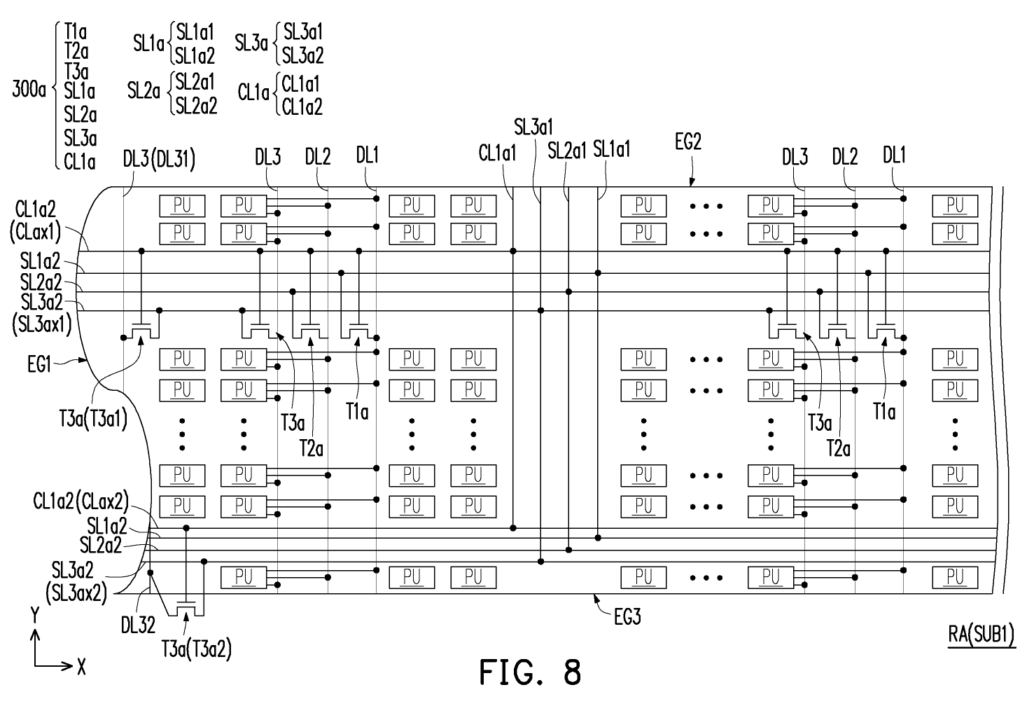

Referring to FIG. 7, the inspection circuit 300 may include a first inspection circuit 300a disposed in the first region RA, a second inspection circuit 300b disposed in the second region RB, and a third inspection circuit 300c disposed in the third region RC. In the electronic device 30, a plurality of data lines can be disposed on the substrate SUB1. However, only data lines DL3 are shown for clarity. As mentioned in the above descriptions, a plurality of data lines DL1, DL2, and DL3 are disposed on the substrate SUB1, as shown in FIG. 8. The data line DL3 is the data line electrically connected to the pixel PX3 in one pixel unit PU. Detailed descriptions are omitted. For ease of explanation, the data lines DL3 can be referred as the first data lines in the following.

FIG. 8 is a schematic enlarged view showing the first region RA of FIG. 7. Referring to FIGS. 7 and 8, the first inspection circuit 300a include first to third signal lines SL1a-SL3a, first to third switching components T1a-T3a, and a control line CL1a electrically connected to the first to third switching components T1a-T3a. The first to third switching components T1a-T3a can be arranged along the second direction X. In some embodiments, in the inspection circuit, the signal line can include a first signal segment (e.g., a connection portion SL1a1, SL2a1 or SL3a1) extending along the first direction Y, and a second signal segment (e.g., a main portion SL1a2, SL2a2 or SL3a2) extending along the second direction X. In some embodiments, the control line can include a first control segment (e.g., a connection portion CL1a1) extending along the first direction Y, and a second control segment (e.g., a main portion CL1a2) extending along the second direction X. Referring to FIG. 8, the connection portions SL1a1-SL3a1 of the signal line are configured to receive test signals transmitted from the edge (e.g., the edge EG2) of the substrate SUB1 respectively, and the main portions SL1a2-SL3a2 of the signal line are electrically connected between the first to third switching components T1a-T3a and the connection portions SL1a1, SL2a1 and SL3a1 respectively. The test signals can be transmitted to the main portions SL1a2, SL2a2 and SL3a2 through the connection portions SL1a1, SL2a1 and SL3a1. The connection portion CL1a1 of the control line is configured to receive a control signal transmitted from the edge (e.g., the edge EG2) of the substrate SUB1, and the main portion CL1a2 of the control line is electrically connected between the control terminal of the first to third switching components T1a-T3a and the connection portion CL1a1 respectively. The control signal can be transmitted to the main portion CL1a2 through the connection portion CL1a1.

In FIG. 8, a portion of the inspection circuit 300a may be disposed in the irregular region. For ease of explanation, data lines DL3 can be taken as an example, and can be referred as the first data lines. In the inspection circuit 300a, the connection between the switching components, the control lines, and the signal lines can refer to the above descriptions for the inspection circuit 100, and detailed descriptions are omitted. In FIG. 8, since the edge EG1 has an irregular contour, the data line nearest to the edge EG1 can be divided into two segments, for example, DL31 and DL32. Therefore, the switching component T3a1 is electrically connected to the data line segment DL31, and the switching component T3a2 is electrically connected to the data line segment DL32. A terminal of the switching component T3a1 is electrically connected to the signal line SL3ax1, and a terminal of the switching component T3a2 is electrically connected to the signal line SL3ax2. The control terminals of the switching components T3a1 and T3a2 are electrically connected to the control lines CLax1 and Clax2, respectively. The control lines CLax1 and Clax2 can extend along the second direction X, and the control line CLa1 extending along direction Y can be electrically connected to the control lines CLax1 and Clax2. In the region RA shown in FIG. 7, the control lines CLax1 and CLax2 are electrically connected to the control line CL1a including segments CLy51 and CLy52. The segment CLy51 is closer to the edge EG2 than the segment CLy52, and the segment CLy52 is connected between the control segments CLax1 and CLax2.

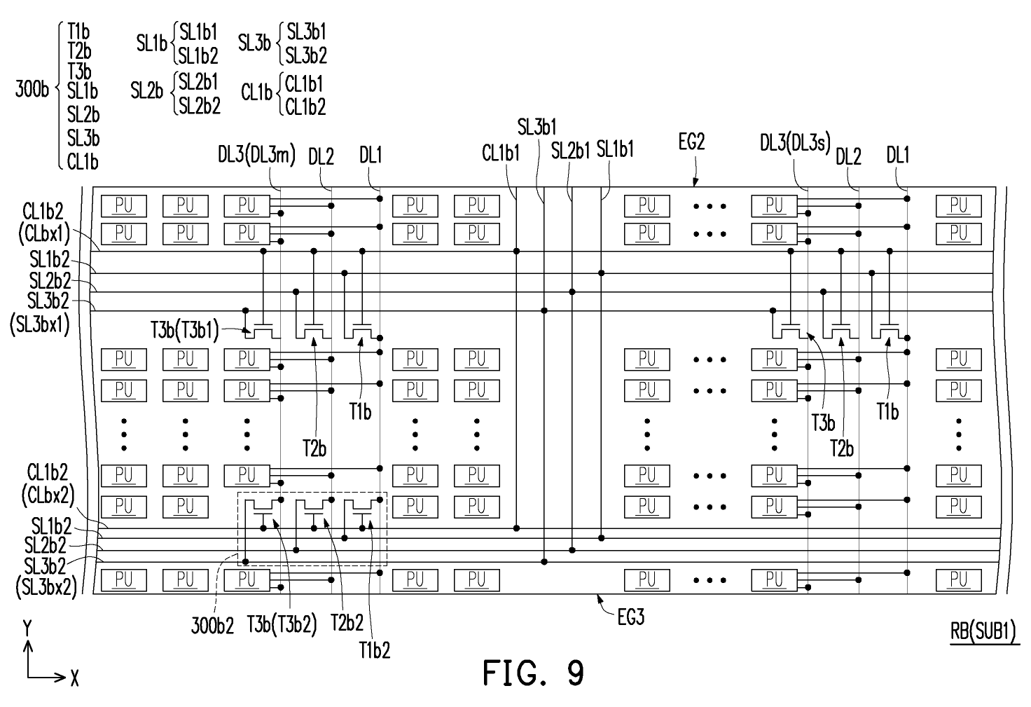

FIG. 9 is a schematic enlarged view showing the second region RB of FIG. 7. Referring to FIG. 7 and upper portion of FIG. 9, the second inspection circuit 300b may include first to third signal lines SL1b-SL3b, first to third switching components T1b-T3b, and a control line CL1b electrically connected to the first to third switching components T1b-T3b. The first to third signal lines SL1b-SL3b may include connection portions SL1b1, SL2b1 and SL3b1 extending along the first direction Y configured to receive test signals transmitted from the edge EG2 of the substrate SUB1, and main portions SL1b2, SL2b2 and SL3b2 extending along the second direction X and electrically connected between the first to third switching components T1b-T3b and the connection portions SL1b1, SL2b1 and SL3b1 respectively. The test signals are transmitted to the main portions SL1b2, SL2b2 and SL3b2 through the connection portions SL1b1, SL2b1 and SL3b1. The control line CL1b may include a connection portion CL1b1 extending along the direction Y configured to receive a control signal transmitted from the edge EG2 of the substrate SUB1, and a main portion CL1b2 extending along the direction X and electrically connected to the first to third switching components T1b-T3b and the connection portion CL1b1 respectively. The control signal is transmitted to the main portion CL1b2 through the connection portion CL1b1. Taking the data line DL3(DL3s) as an example, the number of the switching components T3b electrically to the data line DL3(DL3s) may be single, thus achieving single driving.

In some embodiments, referring to FIG. 9, an additional inspection circuit 300b2 can be disposed on the substrate SUB1 within the active region AA. The additional inspection circuit 300b2 (referring to the lower portion of FIG. 9) may include the control line CLbx2, the first to third signal lines SL1b2-SL3b2, and the first to third switching components T1b2-T3b2 (referring to the bottom left of FIG. 9) electrically connected to the first to third signal lines SL1b2-SL3b2 and the control line CLbx2. Taking the data line DL3(DL3m) as an example, the number of the switching components T3b electrically to the data line DL3(DL3m) may be plural. Two or more than two switching components can be electrically connected to one data line, thus achieving multiple driving. For example, two inspection circuits 300b and 300b2 are electrically connected to one data line DL3m, and two switching components T3b1 and T3b2 are electrically connected to one data line DL3m. The additional inspection circuit 300b can include the switching component T3b2, the corresponding signal line SL3bx2, and the corresponding control line CLbx2. A control terminal of the switching component T3b1 is electrically connected to the control line CLbx1, and a control terminal of the switching component T3b2 is electrically connected to the control line CLbx2. Terminals of the switching component T3b1 and T3b2 are electrically connected to the signal lines SL3bx1 and SL3bx2, respectively. The control line CLbx1 of the inspection circuit 300b and the control line CLbx2 of the inspection circuit 300b2 can be electrically connected by the control line CL1b1. That is to say, the control line CL1b1 can be shared by both of the inspection circuit 300b and the inspection circuit 300b2. The signal line SL3bx1 of the inspection circuit 300b and the signal line SL3bx2 of the inspection circuit 300b2 can be electrically connected by the signal line SL3b1. That is to say, the signal line SL3b1 can be shared by both of the inspection circuit 300b and the inspection circuit 300b2.

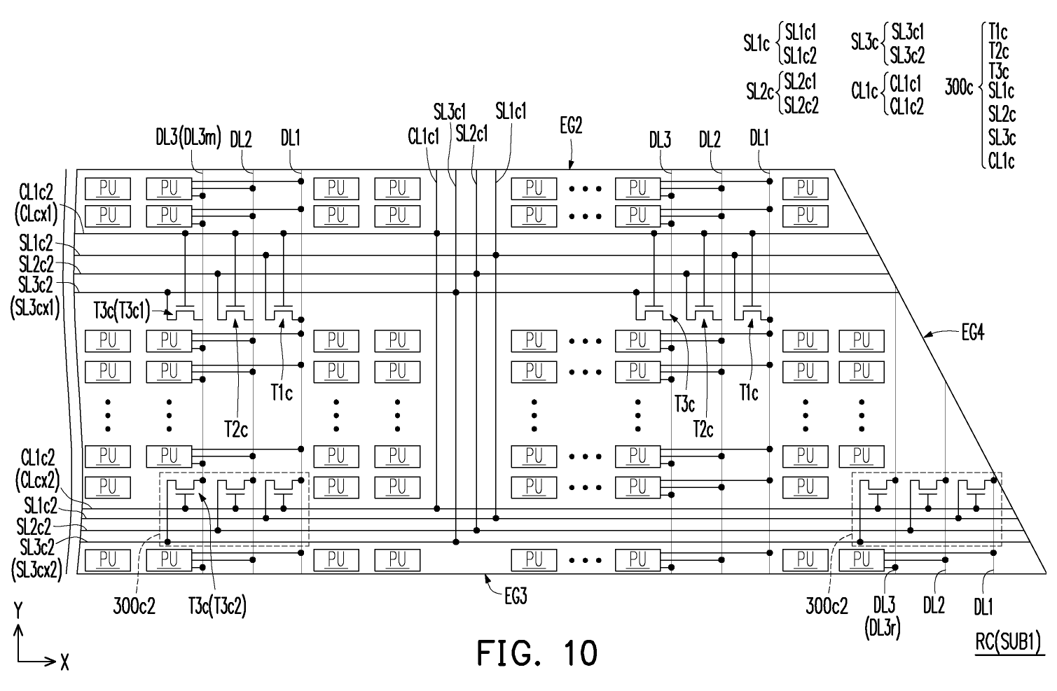

FIG. 10 is a schematic enlarged view showing the third region RC of FIG. 7. Similar to FIGS. 9, in 10, the inspection circuit is disposed in the irregular region RC. Referring to FIGS. 7 and 10, the third inspection circuit 300c (referring to the upper portion of FIG. 10) include first to third signal lines SL1c-SL3c, first to third switching components T1c-T3c, and a control line CL1c. The arrangement of the inspection circuit 300c in FIG. 10 is similar to the inspection circuit 300b in FIG. 9, and detailed descriptions are omitted.

Similar to FIGS. 9, in 10, an additional inspection circuit 300c2 (referring to the lower portion of FIG. 10) is disposed on the substrate SUB1 within the active region AA. Taking the data line DL3(DL3m) as an example, the inspection circuit 300c includes the switching components T3c1 (referring to the upper left of FIG. 10), and the additional inspection circuit 300c2 includes the switching components T3c2 (referring to the bottom left of FIG. 10). The switching components T3c1 and T3c2 are electrically connected to one data line DL3m. Control terminals of the switching components T3c1 and T3c2 are electrically connected to the control lines CLcx1 and CLcx2, respectively. Terminals of the switching component T3c1 and T3c2 are electrically connected to the signal lines SL3cx1 and SL3cx2, respectively. The signal lines SL3cx1 and SL3cx2 can extend along the second direction X and can be electrically connected to the signal line SL3c1 extending along the first direction Y. The control lines CLcx1 and CLcx2 can extend along the second direction X and can be electrically connected to the control line CL1c1 extending along the first direction Y. The arrangement of the additional inspection circuit 300c2 in FIG. 10 is similar to the additional inspection circuit 300b2 in FIG. 9, and detailed descriptions are omitted. Referring to FIG. 7, in the region RC, the control line CL1c may include a control segment CLy6 extending along the first direction Y and electrically connected to the control line CLcx2 of the additional inspection circuit 300c2.

Referring to FIG. 10, since the edge EG4 has an irregular contour, the inspection circuit may be modified to inspect the data line nearest to the edge EG4. Specifically, for the data line DL3r (referring to the bottom right of FIG. 10) nearest to the edge EG4, the data line DL3r can be electrically connected to the additional inspection circuit 300c2 for inspection. For the data line DL3r, the corresponding signal line can be SL3cx2, the corresponding control line can be CLcx2. The connections between the switching components, the signal lines, and the control lines can refer to the above descriptions, and detailed descriptions are omitted. In FIGS. 8 to 10, the switching component T1a, T1b, or T1c may be disposed between the data line DL1 and the data line DL2, the switching component T2a, T2b, or T2c (second switching component) may be disposed between the data line DL2 (second data line) and the data line DL3 (first data line), and the data line DL3 may be disposed between the switching component T2a, T2b, or T2c and the switching component T3a, T3b, or T3c.

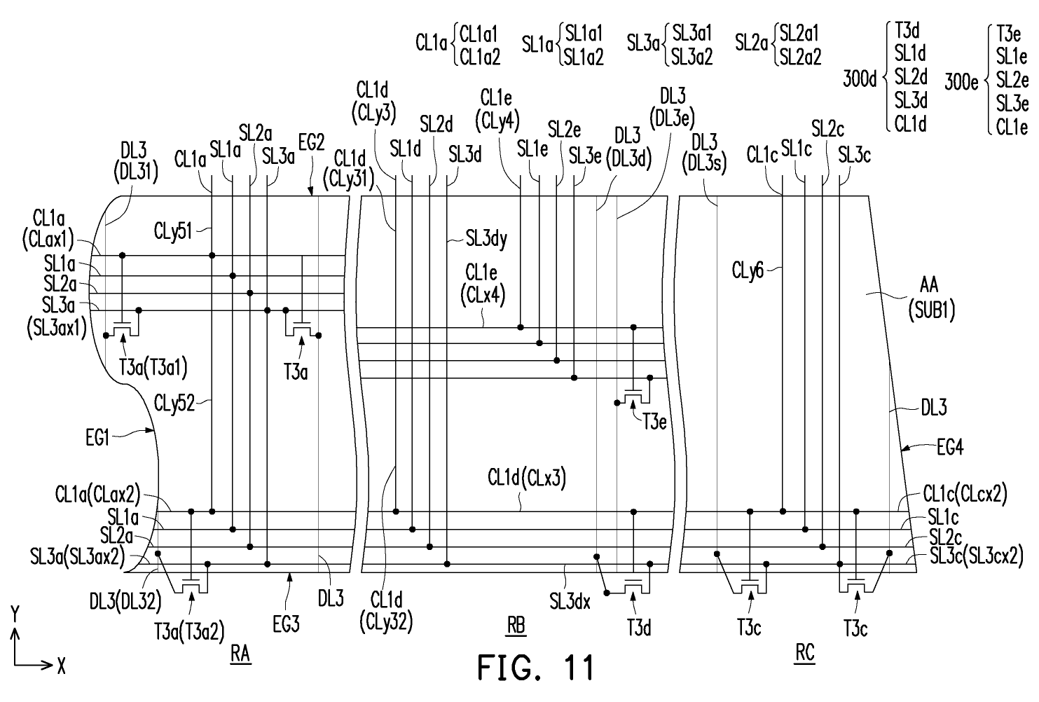

FIG. 11 is a schematic view showing an electronic device according to a fourth embodiment of the present disclosure. The shape and regions of the substrate SUB1 can refer to FIG. 7, and detailed descriptions are omitted. The main difference of FIGS. 11 from 7 is the design of the inspection circuits in the region RB. The inspection circuit arrangement in regions RA and RC of FIG. 11 can refer to FIG. 7, and detailed descriptions are omitted. In FIG. 11, the electronic device includes an inspection circuit 300d and an additional inspection circuit 300e.

Referring to FIG. 11, a plurality of data lines DL, a plurality of switching components, a plurality of signal lines SL (SL1d, SL2d, SL3d, SL1e, SL2e, SL3e), and a plurality of control lines CL are disposed on the substrate SUB1 in region RB. For ease of explanation, the data lines DL3d and DL3e are taken as examples. The switching component T3d are electrically connected to the signal line SL3d, the control line CL1d, and the data line DL3d. Data lines DL2 and DL1 and other switching components respectively connected to the signal lines SL1d and SL2d are omitted for clarity. The control line CL1d can include control segments CLx3 extending along X direction and CLy3 extending along Y direction. Similarly, the signal line SL3d can include a signal segment SL3dy extending along the first direction Y and a signal segment SL3dx extending along the second direction X.

Referring to FIG. 11, the switching component T3e are electrically connected to the signal line SL3e, the control line CL1e, and the data line DL3e. Data lines DL2 and DL1 and other switching components respectively connected to the signal lines SL1e and SL2e are omitted for clarity. Similarly, the control line CL1e can include a control segment CLx4 extending along the second direction X and a control segment CLy4 extending along the first direction Y.

Variations can be made on this design of FIG. 11. In some embodiments, one signal segment extending along the second direction X in regions RA, RB, and RC can be the same, and one control segment extending along the second direction X in regions RA, RB, and RC can be the same. Specifically, the signal segment SL3dx in region RB is electrically connected to the signal segment SL3ax2 in the region RA and the signal segment SL3cx2 in the region RC. Similarly, the control segment CLx3 in region RB is electrically connected to the control segment CLax2 in the region RA and the control segment CLcx2 in the region RC. In this situation, at least one control segment extending to Y direction is disposed. That is, at least one of the control segments including CLy51 and CLy52 and control segments CLy3 and CLy6 extending along the first direction Y are disposed. Specifically, in some variations, the control segment CLy3 is disposed, and the control segments CLy51 and CLy52 and CLy6 are omitted. In other variations, the control segments CLy3 and CLy52 are disposed, and the control segments CLy51 and CLy6 are omitted. In other variations, the control segment including CLy51 and CLy52 and the control segment CLy6 are disposed, and the control segment CLy3 is omitted.

Referring to FIG. 11, the control terminal of the switching component T3d is connected to the control line CL1d, the control terminal of the switching component T3e is connected to the control line CL1e, and the control lines CL1d and the CL1e can be electrically insulated. Specifically, the control line CLx3 and the control line CLx4 are electrically insulated. The control segment CLx4 and the control segment CLy3 are electrically insulated. The data line DL3d can be disposed adjacent to the data line DL3e. In some embodiments, there is no other data line existing between the data lines DL3d and DL3e. Or, in other embodiments, there can be data lines DL1 and /or DL2 disposed between the data lines DL3d and DL3e, but there is no other data line DL3 disposed between the data lines DL3d and DL3e. The switching components T3d and T3e can be arranged along the first direction Y.

Further referring to FIG. 11, in other embodiments, the control line extending along the second direction X in the three regions RA, RB and RC can be different, that is, the control line CLax2 in region RA, the control line CLx3 in region RB, and the control line CLcx2 in region RC are different and are not continuously connected. Each region will have its own control line extending along the first direction Y.

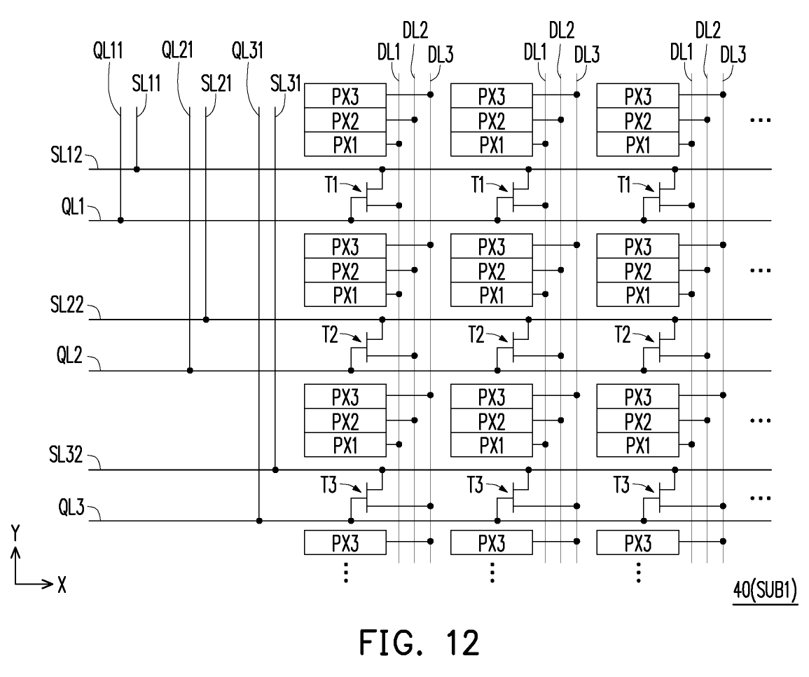

FIG. 12 is a schematic view illustrating an electronic device according to a fifth embodiment of the present disclosure. The main difference between the electronic device 40 in FIG. 12 and the electronic device 20 in FIG. 6 is that each of the control line electrically connected to the switch component includes two segments extending to different directions. Specifically, the control line electrically connected to the switch component T1 includes a first segment (connection portion) QL11 extending along the first direction Y and a second segment (main portion) QL1 extending along the second direction X. The control signal can be provided from an edge (not shown) of the substrate SUB1 through the connection portion QL11. Similarly, the control line electrically connected to the switch component T2 can include two segments QL21 and QL2, and the control line electrically connected to the switch component T3 can include two segments QL31 and QL3, respectively, and detailed descriptions are omitted for clarity.

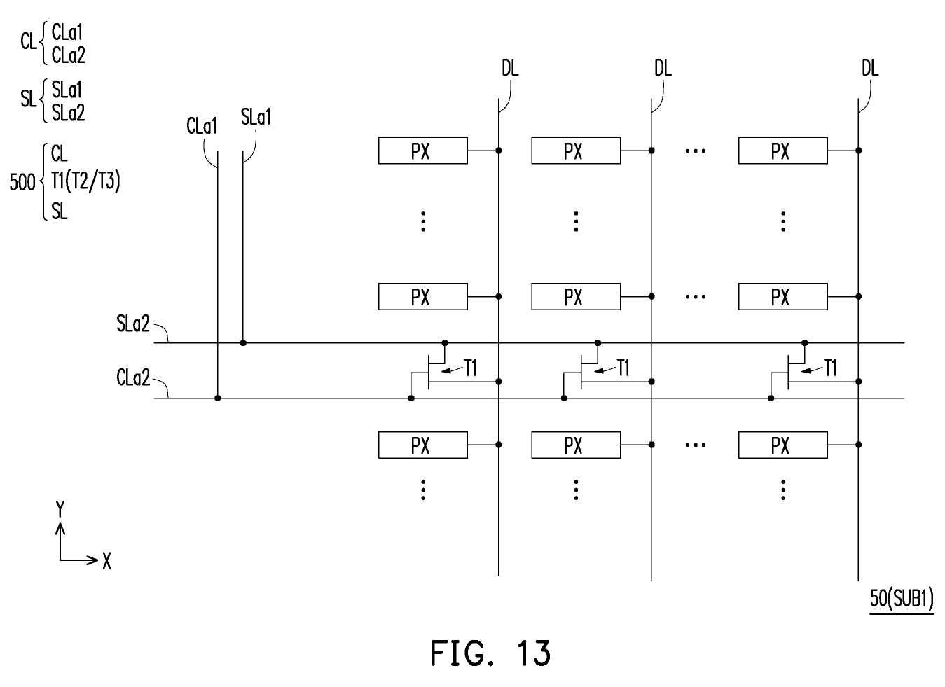

FIG. 13 is a schematic view illustrating an electronic device according to a sixth embodiment of the present disclosure. The electronic device 50 may be or include a monochrome display device. That is, the plurality of pixel units PU disposed on the substrate SUB1 can emit the same single color. The inspection circuit 500 including a plurality of switching components T1 is disposed on the substrate SUB1 within the active region. Taking one switching component T1 as an example, the switching component T1 is electrically connected to the signal line SL and the data line DL. The control line CL is electrically connected to the control terminal of the switching component T1. The signal line SL can include a connection portion SLa1 extending along the first direction Y and a main portion SLa2 extending along the second direction X. The control line CL can include a connection portion CLa1 extending along the first direction Y and a main portion CLa2 extending along the second direction X. The switching component T1 are disposed between two adjacent pixel units PX. The connection relationship between the switching components, the control lines, the signal lines and the data lines can refer to the above descriptions, and redundant explanations are omitted.

Referring to FIG. 14, the electronic device 60 further includes a test circuit 600. As mentioned above, one pixel PX in the pixel unit PU may include one or more electronic components, for example, the transistor TX1 in the pixel PX1. In FIG. 14, the symbol DE1 indicates the electronic component disposed in the pixel unit PU. Some examples of the electronic components can refer the descriptions as mentioned above. For example, the first pixel unit PU can include a driving transistor as an example of the electronic component DE1. The test circuit 600 can be electrically connected to the driving transistor DE1. In some embodiments, the test circuit 600 may include testing pads FB1, FB2, FB3, FB4, FB5 and FB6 electrically connected to the driving transistor DE1 for electrical measurements. For example, the testing pads FB1 and FB2 may be used for measuring the electrical characteristics associated with the gate (e.g., Vg or Vgs-in) of the driving transistor DE1, the testing pads FB3 and FB4 may be used for measuring the electrical characteristics associated with the source (e.g., Ids or Vs) of the driving transistor DE1, and the testing pads FB5 and FB6 may be used for measuring the electrical characteristics associated with the drain (e.g., Ids or Vd) of the driving transistor DE1. In some embodiments, test circuit 600 can be electrically connected to the electronic component disposed in the inspection circuit 100, for example, the first switching component T1 disposed in the inspection circuit 100. The testing pads FB1 to FB6 may be disposed outside the edge of the substrate SUB1, for example, disposed on a circuit board, such as a flexible printed circuit (not shown). In some embodiments, the test circuit 600 and the testing pads can be disposed on the first surface FS1 of the substrate SUB1, or on the back surface BS2 of the substrate SUB1.

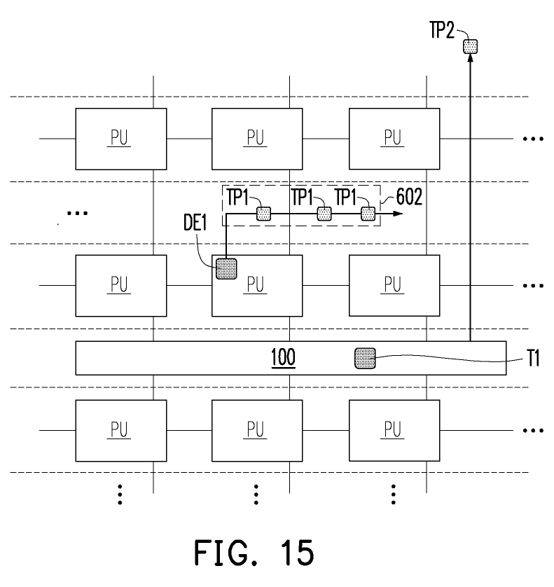

Referring to FIG. 15, the electronic device further includes a test circuit 602 disposed on the substrate SUB1 within the active region. Specifically, the test circuit 602 may be disposed in the active region AA1, for example, disposed between the pixel units PU, for example, disposed between the first pixel PU and the second pixel PU. The test circuit 602 may include a testing pad TP1, and the number of the testing pads TP1 can be plural. In some embodiments, the test circuit 602 can be electrically connected to the electronic component disposed in the inspection circuit 100, for example, the first switching component T1 disposed in the inspection circuit 100.

In summary, in the electronic device described in the above embodiments, the inspection circuit is disposed on the substrate within the active region, so that the area of the peripheral region surrounding the active region can be minimized, and thereby providing advantages to a narrow border design or borderless design.

What is claimed is:

1. An electronic device, comprising:
a substrate comprising an active region;
a first data line disposed on the substrate and extending along a first direction;
a first pixel unit disposed on the substrate within the active region and electrically connected to the first data line;
a second pixel unit disposed on the substrate within the active region and electrically connected to the first data line; and
an inspection circuit disposed on the substrate within the active region, wherein the inspection circuit comprises a first signal line, a first switching component disposed between the first pixel unit and the second pixel unit and electrically connected to the first signal line and the first data line, and a first control line electrically connected to a control terminal of the first switching component.

2. The electronic device of claim 1, further comprising a second data line disposed on the substrate and extending along the first direction, wherein each of the first pixel unit and the second pixel unit comprises a first pixel electrically connected to the first data line and a second pixel electrically connected to the second data line.

3. The electronic device of claim 2, wherein the inspection circuit further comprises:
a second signal line extending along a second direction different from the first direction; and
a second switching component electrically connected to the second data line and the second signal line.

4. The electronic device of claim 3, wherein the inspection circuit further comprises a common gate line electrically connected to the first control line, the first switching component and the second switching component.

5. The electronic device of claim 3, wherein the first data line has a first side and a second side oppositely disposed, and the second side is closer to the second data line than the first side,
wherein the first switching component and the second switching component are at the first side of the first data line, and arranged along the first direction.

6. The electronic device of claim 3, wherein the second switching component is disposed between the first pixel unit and the second pixel unit.

7. The electronic device of claim 3, further comprising a third pixel unit disposed on the substrate within the active region and electrically connected to the first data line, wherein the second switching component is disposed between the second pixel unit and the third pixel unit.

8. The electronic device of claim 3, wherein the second switching component is disposed between the first data line and the second data line, and the first switching component and the second switching component are arranged along the second direction.

9. The electronic device of claim 3, wherein the first control line is electrically connected to a control terminal of the second switching component.

10. The electronic device of claim 3, wherein the inspection circuit further comprise a second control line electrically connected to a control terminal of the second switching component.

11. The electronic device of claim 10, wherein the first control line and the second control line extend along the second direction, and the inspection circuit further comprises:
a connection line extending along a direction different from the second direction, and electrically connected to the first control line and the second control line.

12. The electronic device of claim 1, wherein the first signal line comprises:
a first main portion extending along a second direction different from the first direction; and
a first connection portion extending along a direction different from the second direction,
wherein the first main portion is electrically connected between the first switching component and the first connection portion.

13. The electronic device of claim 1, wherein the first control line comprises:
a second main portion extending along a second direction different from the first direction; and
a second connection portion extending along a direction different from the second direction,
wherein the second main portion is electrically connected between the control terminal of the first switching component and the second connection portion.

14. The electronic device of claim 1, wherein the substrate comprises an irregular region having an edge with an irregular contour, and a portion of the inspection circuit is disposed in the irregular region.

15. The electronic device of claim 1, further comprising:
an additional inspection circuit disposed on the substrate within the active region, wherein the additional inspection circuit comprises an additional signal line, an additional switching component electrically connected to the additional signal line and the first data line, and an additional control line electrically connected to a control terminal of the additional switching component.

16. The electronic device of claim 15, wherein the first control line and the additional control line are electrically connected.

17. The electronic device of claim 15, wherein the first control line and the additional control line are electrically insulated.

18. The electronic device of claim 1, wherein the first pixel unit comprises an electronic component, and the electronic device comprises a test circuit electrically connected to at least one of the first switching component of the inspection circuit and the electronic component of the first pixel unit.

19. The electronic device of claim 18, wherein the test circuit comprises a testing pad disposed between the first pixel unit and the second pixel unit.
